(19) United States
(12) Patent Application Publication
(10) Pub. No.: US 2009/0244848 A1
(43) Pub. Date: Oct. 1, 2009

(54) Power Device Substrates and Power Device Packages Including the Same

(76) Inventors: Seung-won Lim, Gyeonggi-do (KR); O-soeb Jeon, Seoul (KR); Seung-yong Choi, Seoul (KR); Joon-seo Son, Seoul (KR); Man-kyo Jong, Gyeonggi-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/336,437

(22) Filed: Dec. 16, 2008

(30) Foreign Application Priority Data
Mar. 28, 2008 (KR) 10-2008-0029312

(51) Int. Cl. H05K 7/20

(52) U.S. Cl. 361/709

(57) ABSTRACT

Provided are power device substrates that comprise thermally conductive plastic materials, and power device packages including the same. An exemplary power device package includes a power device substrate that comprises a thermally conductive plastic material, and has a first principal plane that provides an electrically insulating surface and a second principal plane of which at least a portion is exposed outside a molding member. The exemplary power device package further includes one or more power devices disposed on the first principal plane of the power device substrate, and a plurality of conductive members that are electrically connected to the power device(s) in order to electrically connect the power device(s) to an external circuit.

### CROSS-REFERENCES TO RELATED APPLICATIONS

This application claims the benefit of Korean Patent Application No. 10-2008-0029312, filed on Mar. 28, 2008, in the Korean Intellectual Property Office, the disclosure of which is incorporated herein in its entirety by reference.

### BACKGROUND OF THE INVENTION

1. Field of the Invention

The present invention relates to a substrate and a semiconductor package including the same, and more particularly, to a power device substrate and a power device package including the same.

2. Description of the Related Art

Recent developments in power electronics, including such power devices as servo drivers, inverters, silicon-controlled rectifiers (SCRs) and converters, are leading to the manufacturing of lightweight and small power devices with excellent performance characteristics. Related research is being actively conducted into smart or intelligent power modules in which a variety of power semiconductor chips and low power semiconductor chips, such as IC chips for controlling the power semiconductor chips, can be integrated into one package.

Conventionally, a ceramic substrate, a direct bonded copper (DBC) substrate, or an insulated metal substrate (IMS) is used as a power semiconductor substrate for mounting power semiconductor chips. The power semiconductor substrate functions to provide interconnections to the power semiconductor chips, like the function of a printed circuit board (PCB), or to cool mounted components. Compared to techniques and materials used to mount a low-power circuit device (such as a logic circuit) to a substrate, the power semiconductor substrate needs to provide electrical insulation having high breakdown strength, and durability against repetitive heat cycles during the operations of a circuit device mounted thereon. Each of the ceramic substrate, the DBC substrate, and the IMS basically uses a highly durable metal or ceramic material, and thus satisfies the above-mentioned requirement.

However, in the case of the ceramic substrate or the DBC substrate which is formed of a ceramic material such as an aluminum oxide, an aluminum nitride, or a beryllium oxide, failures may frequently occur. These failures are often due to cracks that inadvertently form during the manufacturing of the semiconductor packages. Also, the ceramic material is not easily processed and is relatively expensive. In the case of the IMS, an epoxy-based dielectric layer having a low thermal conductivity is used between a metal base plate and a copper (Cu) wiring pattern and thus heat dissipation efficiency is low.

### SUMMARY OF THE INVENTION

The present invention provides power device substrates that can provide lightweight power devices, that can be easily processed and easily handled due to low susceptibility to mechanical and thermal shock, and that can have excellent heat dissipation efficiencies.

The present invention also provides various power device packages using the power device substrates.

According to an aspect of the present invention, there is provided a power device substrate comprising: a first principal plane on which a power device is disposed (e.g., mounted) and which provides an electrically insulating surface; a second principal plane that is opposite the first principal plane and provides a heat dissipation surface; and a substrate body layer that provides a heat transfer path between the first and second principal planes and that is formed of a thermally conductive plastic material.

In some embodiments, the power device substrate may further comprise a conductive pattern that is electrically connected to the power device on the first principal plane. The conductive pattern may comprise at least one of an interconnection pattern and a die attach paddle. The substrate body layer may have a thermal conductivity of 5-20 Watt/meter-Kelvin (W/mK) and have a thickness of 0.5-2.0 mm.

According to another aspect of the present invention, there is provided a power device package comprising: a power device substrate having a first principal plane that provides an electrically insulating surface, a second principal plane of which at least a portion is exposed outside a molding member, and a substrate body layer that provides a heat transfer path between the first and second principal planes, wherein the substrate body layer is formed of a thermally conductive plastic material; one or more power devices disposed (e.g., mounted) on the first principal plane of the power device substrate; and a plurality of conductive members that are electrically connected to the power device in order to electrically connect the power device to an external circuit.

In some embodiments, the power device substrate may further comprise a conductive pattern disposed on the first principal plane. The conductive pattern may comprise copper (Cu), or aluminum (Al), or an alloy thereof. The conductive pattern may comprise an interconnection pattern that is electrically connected to at least one of the conductive members or to at least one of the power devices. Also, the conductive pattern may comprise one or more die attach paddles on which the power devices are disposed (e.g., mounted).

In some embodiments, the conductive members may comprise leads that are provided by a lead frame. The lead frame may be attached on the first principal plane of the power device substrate by a conductive or non-conductive adhesive member. The lead frame may comprise one or more die attach paddles on which the power devices are disposed (e.g., mounted).

The power device package may further comprise one or more low-power control devices for controlling the power devices. The low-power control device(s) may be disposed (e.g., mounted) on the first principal plane of the power device substrate. Alternatively, the low-power control device(s) may be disposed (e.g., mounted) on a control device substrate that is separate from the power device substrate. In this case, the control device substrate may comprise a die attach paddle that is provided by a lead frame. Also, the control device substrate may comprise at least one of a printed circuit board (PCB), an insulated metal substrate (IMS), a pre-molded substrate, a direct bonded copper (DBC) substrate, and a flexible PCB (FPCB).

Also, in some embodiments, the second principal plane may comprise a plurality of protrusive patterns for increasing a surface area of the second principal plane. Thus, although the heat sink may be not attached, the second principal plane may achieve the same thermal dissipation effect as, or an effect superior to, a heat sink.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1C are perspective views of power device substrates that comprise thermally conductive plastic materials, according to various embodiments of the present invention;

FIG. 2A is a perspective view of a power device package according to an embodiment of the present invention;

FIG. 2B is a cross-sectional view of the power device package illustrated in FIG. 2A, as taken along a line II-II, according to an embodiment of the present invention; and

FIGS. 3A through 3C are cross-sectional views of power device packages according to other embodiments of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to those of ordinary skill in the art.

It will also be understood that when a layer is referred to as being “on” another layer or substrate, it can be directly on the other layer or substrate, or intervening layers may also be present. It will also be understood that when an element, such as a wire, a lead, a layer, a region, or a substrate, is referred to as being “on,” “connected to,” “electrically connected to,” “coupled to,” or “electrically coupled to” another element, it may be directly on, connected or coupled to the other element, or one or more intervening elements may be present. In contrast, when an element is referred to as being “directly on,” “directly connected to,” “directly coupled to,” or “directly electrically connected to” another element, there are no intervening elements present. In the drawings, the thicknesses of layers and regions are exaggerated for clarity. Like reference numerals in the drawings denote like elements. As used herein, the term “and/or” refers to one of or a combination of at least two of listed items.

The terminology used herein is for the purpose of describing particular embodiments and is not intended to limiting the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Spatially relative terms, such as “over,” “above,” “upper,” “under,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device (e.g., package) in use or operation in addition to the orientation depicted in the figures. For example, if the device in the figures is turned over, elements described as “below” or “beneath” or “under” other elements or features would then be oriented “over” or “above” the other elements or features. Thus, the exemplary term “above” may encompass both an above and below orientation.

It will be understood that, although the terms “first,” “second,” “third,” etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The present invention will now be described more fully with reference to the accompanying drawings, in which exemplary embodiments of the invention are shown. In the drawings, modification of the illustrated shapes may be expected according to the manufacturing technique and/or tolerance in the drawings. Accordingly, the embodiments of the present invention should not be construed as being limited to the particular forms in the illustrated drawings, and should include changes in the shape caused during the manufacturing process.

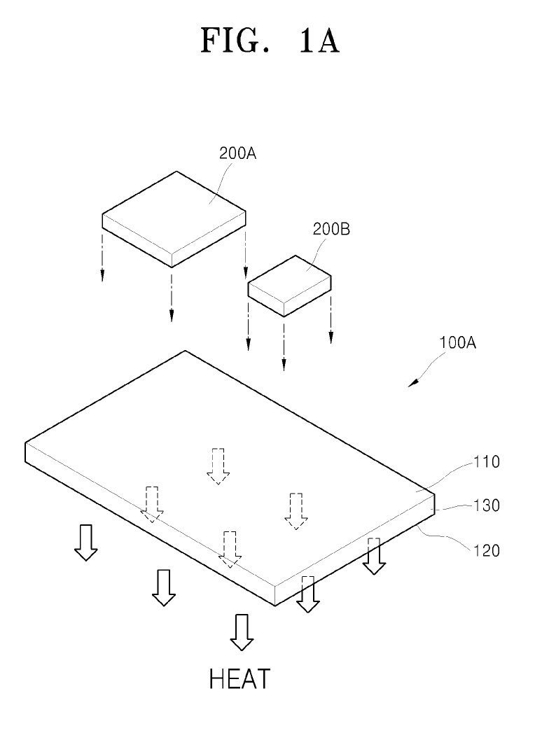

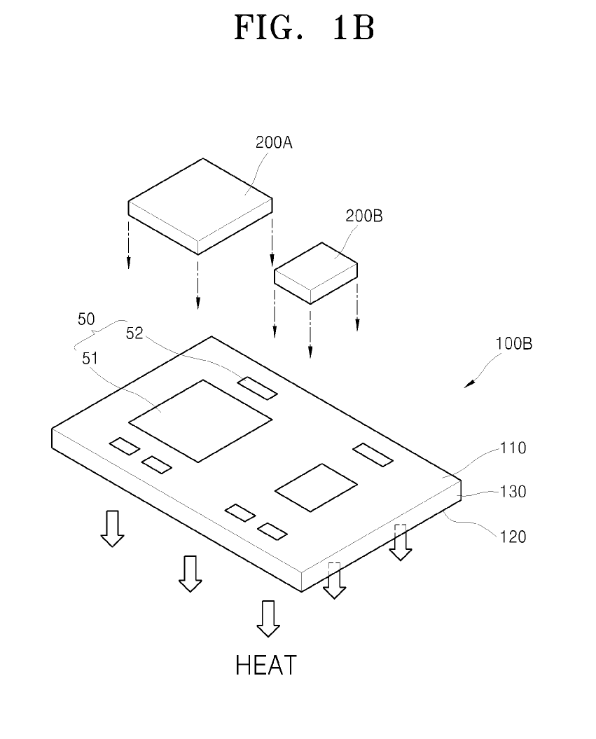

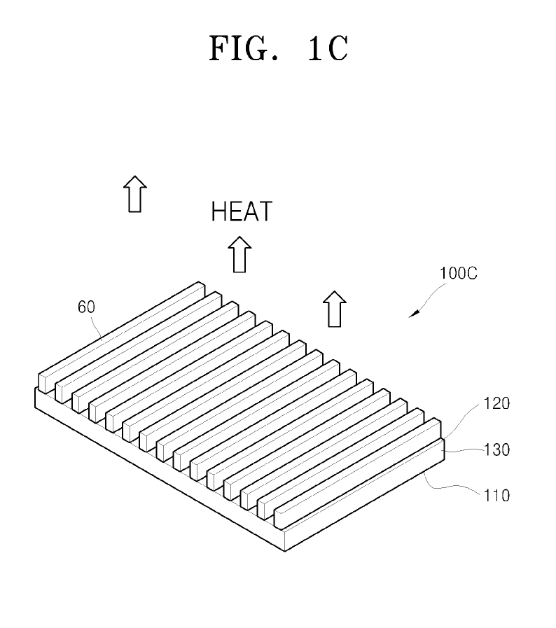

FIGS. 1A through 1C are perspective views of power device substrates 100A, 100B, and 100C, respectively, which comprise a thermally conductive plastic material, according to various embodiments of the present invention.

Referring to FIGS. 1A through 1C, each of the power device substrates 100A, 100B, and 100C includes: a first principal plane 110 that provides an electrically insulating surface on which various power devices 200A and 200B are disposed (e.g., mounted); a second principal plane 120 that is opposite the first principal plane 110 and that provides a heat dissipation surface; and a substrate body layer 130 that provides a heat transfer path between the first and second principal planes 110 and 120. Each of the power device substrates 100A, 100B, and 100C emits heat that is generated by the power devices 200A and 200B disposed on the first principal plane 110, from a surface of the second principal plane 120, as indicated by the arrows in the figures.

The substrate body layer 130 is formed of a thermally conductive plastic material, preferably having a thermal conductivity of at least 1 W/mK. Thermally conductive plastic materials are commercially available; they comprise a homogeneous composition of one or more polymer materials, and may have one or more solid filler materials in particulate and/or powdered form, mixed with the polymer(s) in a homogeneous manner. The solid filler materials typically comprise inorganic materials. For example, a product having a brand name CoolPoly® of II Kwang Polymer Co., Ltd. located in GyeongGi-do, Korea, may be used to provide the thermally conductive plastic material. This thermally conductive plastic material has an excellent thermal conductivity comparable to metal and ceramic materials, while it has general plastic characteristics such as being lightweight and having a small thermal expansion coefficient. CoolPoly® comprises a liquid crystalline polymer and one or more fillers, has a homogeneous composition, and can be injected molded, such as mold substrate body layer 130 into a desired form. A conventional plastic substrate has a low thermal conductivity of, for example, 0.2 Watt/meter-Kelvin (W/mK). However, the thermally conductive plastic material has a high thermal conductivity of 1-100 W/mK. In order to replace a ceramic substrate, a direct bonded copper (DBC) substrate, or an insulated metal substrate (IMS), the thermally conductive plastic material may have a thermal conductivity of 5-100 W/mK, and preferably, 10-100 W/mK. The thermally conductive plastic material may have a thickness of, for example, 0.5-2.0 mm. Substrate body layer 130 preferably comprises at least 50% of the volume of the power device substrate (e.g., each of substrates 100A-100C), and more preferably at least 75% o the volume. In typical embodiments, Substrate body layer 130 comprises at least 90% to at least 95% of the volume of the power device substrate. However, the above-mentioned percentages and numerical values are only examples, and the power device substrates 100A, 100B, and 100C are not limited thereto.

As described above, the first principal plane 110 of the power device substrate 100A may provide an electrically insulating surface. Optionally, as illustrated in FIG. 1B, conductive patterns 50 may be disposed (e.g., formed) on the first principal plane 110 of the power device substrate 100B. At least one of the conductive patterns 50 may provide interconnection patterns 52 that may be electrically connected to leads of a lead frame and/or the power devices 200A and 200B, which will be described in detail later. Also, the conductive patterns 50 may provide a die attach paddles 51 for attaching the power devices 200A and 200B onto the first principal plane 110. The conductive patterns 50 may comprise copper (Cu), aluminum (Al), or an alloy thereof. As is well-known in the art, the conductive patterns 50 may be disposed (e.g., formed) by, for example, a non-electrolytic process (e.g., electroless plating) and an appropriate patterning process.

The second principal plane 120 of each of the power device substrates 100A, 100B, and 100C provides the heat dissipation surface from which heat that is generated by the power devices 200A and 200B on the first principal plane 110, and that is emitted through the substrate body layer 130, is dissipated to the outside of a semiconductor package. A heat sink (not shown) may be attached on an exposed surface of the second principal plane 120 so as to increase heat dissipation efficiency.

Optionally, protrusive patterns may be formed on the second principal plane 120 so as to increase an area of the heat dissipation surface. The second principal plane 120 may be processed into various forms due to a unique and excellent plastic characteristic that the thermally conductive plastic material has as a polymer material, in comparison to a conventional ceramic or metal substrate. For example, as illustrated in FIG. 1C, the surface of the second principal plane 120 may have a wrinkled (e.g., finned) structure 60 having line patterns. However, the present invention is not limited thereto and the surface of the second principal plane 120 may have, for example, a grid structure or a wrinkled structure having uniformly aligned wave patterns.

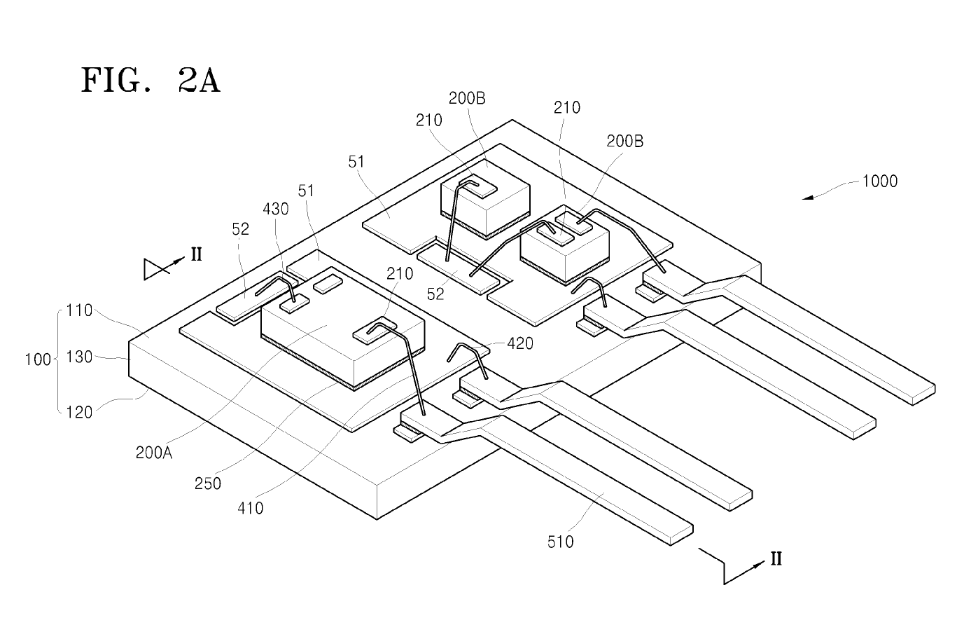

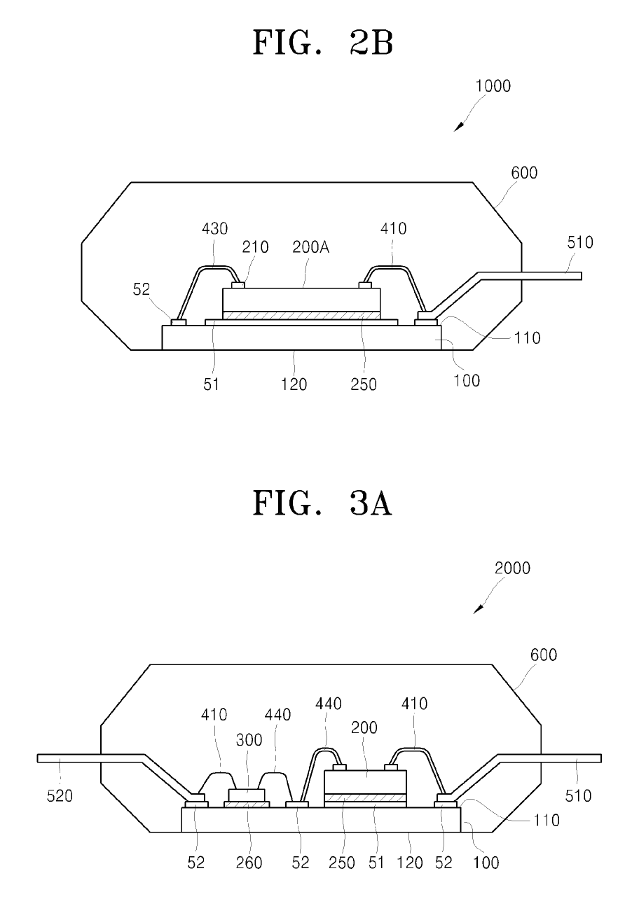

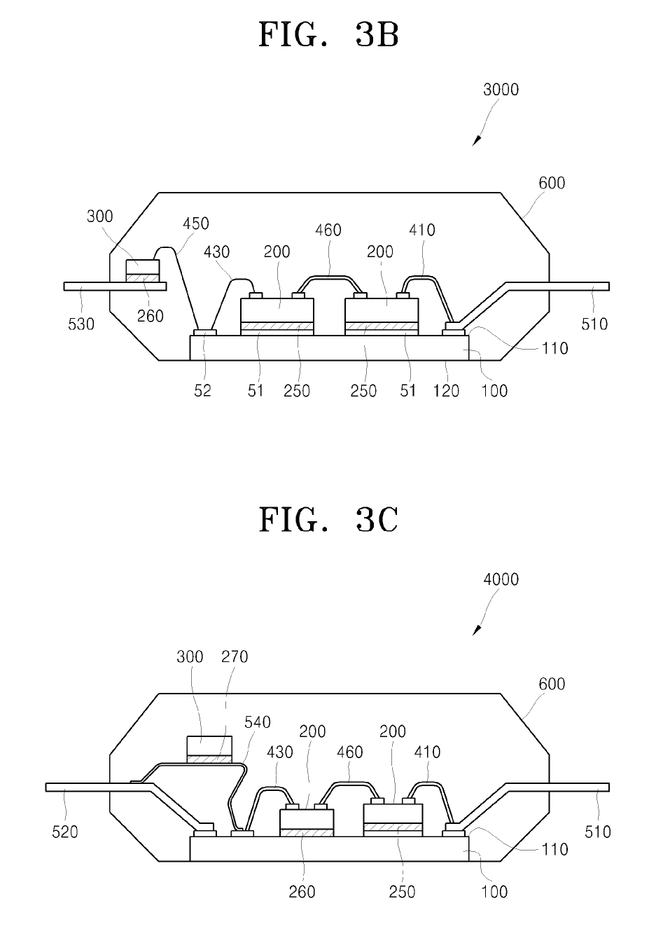

As described above, the protrusive surface of the second principal plane 120 of each of the power device substrates 100A, 100B, and 100C increases the area of the heat dissipation surface. Thus, although a heat sink is not attached, the second principal plane 120 may achieve the same effect as an attached heat sink, or an effect superior to that of an attached heat sink. Various power device packages including the power device substrate 100A, 100B, or 100C will now be described with reference to FIGS. 2A through 2B and 3A through 3C.

FIG. 2A is a perspective view of a power device package 1000 according to an embodiment of the present invention. FIG. 2B is a cross-sectional view of the power device package 100 illustrated in FIG. 2A, as taken along a line II-II, according to an embodiment of the present invention. For convenience of explanation, a molding member 600 for protecting internal components thereof is omitted in FIG. 2A. However, the molding member 600 is fully illustrated in FIG. 2B.

Referring to FIGS. 2A and 2B, the power device package 1000 includes a power device substrate 100. For example, the power device substrate 100 may comprise the power device substrate 100A, 100B or 100C, as respectively illustrated in FIG. 1A through 1C. One or more power devices 200A and 200B are disposed (e.g., mounted) on a first principal plane 110 of the power device substrate 100. As is well-known in the art, each of the power devices 200A and 200B may comprise, for example, a MOSFET, a bipolar junction transistor (BJT), an insulated gated BJT or a diode for implementing a servo driver, an inverter, a power regulator, a converter device, etc. The above-mentioned devices are only examples and the power device package 1000 is not limited thereto.

A conductive material such as a lead frame (not shown), for providing a plurality of leads 510, may be disposed on the first principal plane 110 of the power device substrate 100. Leads 510 are electrically connected to the power devices 200A and 200B in order to connect the power device substrate 100 to an external circuit. The lead frame may be attached on the first principal plane 110 of the power device substrate 100 by non-conductive adhesive members such as elastomer, epoxy, solder and high temperature tape such as silicon tape, glass tape and ceramic tape by conductive adhesive members such as conductive epoxy. At least one of the leads 510 may be electrically connected to connection pads 210 of the power devices 200A and 200B through wires 410. Also, at least another one of the leads 510 may be electrically connected to interconnection patterns 52 formed on the power device substrate 100 through wires 420. Also, at least one of the contact pads 210 of the power devices 200A and 200B may be electrically connected to the interconnection pattern 52 through wires 430.

When the lower surfaces of the power devices 200A and/or 200B are used as electrodes, die attach paddles 51 may be provided between the power devices 200A and/or 200B and the first principal plane 110 of the power device substrate 100. In this case, the power devices 200A and 200B may be attached on the die attach paddles 51 by conductive adhesive members 250 such as a metallic epoxy or solder. Alternatively, the die attach paddles 51 for attaching the power devices 200A and 200B onto the first principal plane 110 may also be provided by the lead frame (not shown).

At least a portion of the second principal plane 120 of the power device substrate 100 may be exposed outside the molding member 600, and functions as a heat dissipation surface. In order to improve heat dissipation efficiency, a heat sink (not shown) may be attached on the exposed portion of the second principal plane 120 of the power device substrate 100. Alternatively, as the power device substrate 100C illustrated in FIG. 1C, a wrinkled structure 60 may be formed on the second principal plane 120 so as to replace the heat sink.

The molding member 600 may be formed by performing a transfer molding process using a thermosetting resin such as an epoxy mold compound (EMC). In this case, both the power device substrate 100 and the molding member 600 comprise polymer-based materials. Thus, a discrepancy in thermal expansion coefficients between the power device substrate 100 and the molding member 600 is small and excellent durability and long life may be ensured against a repetitive heat cycle of a resultant product.

FIGS. 3A through 3C are cross-sectional views of power device packages 2000, 3000, and 4000, respectively, according to other embodiments of the present invention.

Referring to FIGS. 3A through 3C, unlike the power device package 1000 illustrated in FIGS. 2A and 2B, each of the power device packages 2000, 3000, and 4000 includes at least one low-power control device 300 for controlling a power devices 200.

As illustrated in FIG. 3A, the low-power control device 300 may be disposed (e.g., mounted) on a power device substrate 100, together with the power device 200. The low-power control device 300 may be electrically connected to interconnection patterns 52 formed on the first principal plane 110 of the power device substrate 100, or to a contact pad 210 of the power device 200, through wires 440. Also, at least one of leads 520 may be electrically connected to the low-power control device 300 in order to transmit a control signal.

In some embodiments of the present invention, in order to reduce or prevent thermal cross talk that may occur between the power device 200 and the low-power control device 300, as illustrated in FIGS. 3B and 3C, the low-power control device 300 may be (e.g., mounted) on a control device substrate 530 or 540 that is separate from the power device substrate 100. Heat dissipation efficiency matters less for the control device substrate on which the low-power control device 300 is disposed, in comparison to the power device 200. Thus, the control device substrate may be entirely encapsulated by a molding member 600. The power device 200 and the low-power control device 300 may be electrically connected to each other through wires 430 and/or 450.

As illustrated in FIG. 3B, the control device substrate may comprise a die attach paddle provided by a lead frame 530. However, the control device substrate is not limited thereto and may comprise a well-known printed circuit board (PCB) or a well-known ceramic substrate that are disposed in the molding member 600.

Alternatively, as illustrated in FIG. 3C, the control device substrate may comprise a flexible PCB (FPCB) 540. The low-power control device 300 may be disposed on the FPCB 540 by bonding. The low-power control device 300 may be electrically connected to the FPCB 540 through a bonding layer 270, such as a conductive bump or a solder ball. When the low-power control device 300 is disposed on the FPCB 540, the height of the power device package 4000 may be reduced. Thus, a resultant package product may be minimized. Wires 450 and 460 are used for electrical connection between the power devices 200 and the low-power control device 300.

As described above, not only by integrating various power semiconductor chips into a package, but also by integrating a control device (such as an integrated-chip, or IC) for controlling the power semiconductor chips together into the package, a smart or intelligent power module may be provided.

Hereinabove, a lower surface of a power device or a control device is described as being bonded with a substrate. However, the present invention is not limited thereto. For example, the power device or the control device may be bonded with the substrate, in a well-known form such as a flip-chip. In addition, a lead is exemplarily shown as a conductive element for connecting the power device or the control device, that are encapsulated in a package, to an external circuit. However, the conductive material is not limited to the lead and may comprise a tap, a ball, or a bump for forming a leadless package. Furthermore, it is well understood that a package in which two or more power devices are stacked is also included in the scope of the present invention.

A conventional substrate, such as a PCB, a ceramic substrate, a DBC substrate, or an IMS, may be disposed between a power device substrate and a power device according to the present invention. In this case, a portion of a second principal plane of the power device substrate may be exposed outside a molding member and may function as a heat sink for emitting heat, created from the power device substrate, to the outside of a package.

As described above, according to the embodiments of the present invention, by using a power device substrate having a substrate body layer of a polymer-based thermally conductive plastic material, a small and lightweight power device package may be implemented. Also, the power device substrate can be easily processed and easily handled due to low susceptibility to mechanical and thermal shock, while it has an excellent heat dissipation efficiency.

In addition, according to the embodiments of the present invention, the difference between the thermal expansion coefficients of the power device substrate and a molding member may be small, and thus various power device packages having a long life and excellent durability may be provided.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A power device substrate comprising:
a first principal plane on which a power device is disposed and which provides an electrically insulating surface;
a second principal plane that is opposite the first principal plane and provides a heat dissipation surface; and
a substrate body layer that provides a heat transfer path between the first and second principal planes and that is formed of a thermally conductive plastic material.

2. The power device substrate of claim 1, further comprising a conductive pattern that is disposed on the first principal plane and that is electrically connected to the power device.

3. The power device substrate of claim 2, wherein the conductive pattern comprises at least one of an interconnection pattern or a die attach paddle.

4. The power device substrate of claim 1, wherein the substrate body layer has a thermal conductivity of 5-20 Watt/meter-Kelvin (W/mK).

5. The power device substrate of claim 1, wherein the substrate body layer has a thickness of 0.5-2.0 mm.

6. The power device substrate of claim 1, wherein the second principal plane comprises a plurality of protrusive patterns for increasing a surface area of the second principal plane.

7. A power device package comprising:
a power device substrate having a first principal plane that provides an electrically insulating surface, a second principal plane of which at least a portion is exposed outside a molding member, and a substrate body layer that provides a heat transfer path between the first and second principal planes, wherein the substrate body layer is formed of a thermally conductive plastic material;
one or more power devices disposed on the first principal plane of the power device substrate; and
a plurality of conductive members that are electrically connected to the power device in order to electrically connect the power device to an external circuit.

8. The power device package of claim 7, wherein the power device substrate further comprises a conductive pattern disposed on the first principal plane.

9. The power device package of claim 8, wherein the conductive pattern comprises copper, aluminum, or an alloy thereof.

10. The power device package of claim 8, wherein the conductive pattern comprises an interconnection pattern that is electrically connected to at least one of the conductive members or to at least one power device.

11. The power device package of claim 8, wherein the conductive pattern comprises one or more die attach paddles on which the power devices are disposed.

12. The power device package of claim 7, wherein the conductive members comprise leads that are provided by a lead frame.

13. The power device package of claim 12, wherein the lead frame is attached on the first principal plane of the power device substrate by a conductive or non-conductive adhesive member.

14. The power device package of claim 13, wherein the conductive adhesive member comprises a metallic epoxy or solder.

15. The power device package of claim 13, wherein the non-conductive adhesive member comprises a silicon elastomer or a non-conductive epoxy.

16. The power device package of claim 12, wherein the lead frame comprises one or more die attach paddles on which the power devices are disposed.

17. The power device package of claim 7, further comprising a heat sink that is attached on at least a portion of the exposed portion of the second principal plane of the power device substrate.

18. The power device package of claim 7, further comprising one or more low-power control devices for controlling the one or more power devices.

19. The power device package of claim 18, wherein the low-power control devices are disposed on the first principal plane of the power device substrate.

20. The power device package of claim 18, wherein the low-power control devices are disposed on a control device substrate that is separate from the power device substrate.

21. The power device package of claim 20, wherein the control device substrate comprises a die attach paddle provided by a lead frame.

22. The power device package of claim 20, wherein the control device substrate comprises at least one of a printed circuit board (PCB), an insulated metal substrate (IMS), a pre-molded substrate, a direct bonded copper (DBC) substrate, or a flexible PCB (FPCB).

23. The power device package of claim 18, wherein at least one power device is electrically connected to at least one low-power control device by a wire bonding method.

24. The power device package of claim 7, wherein the power device substrate has a thermal conductivity of 5-20 Watt/meter-Kelvin (W/mK).

25. The power device package of claim 7, wherein the power device substrate has a thickness of 0.5-2.0 mm.

26. The power device package of claim 7, wherein the second principal plane comprises a plurality of protrusive patterns for increasing a surface area of the second principal plane.
